(19) United States
(12) Patent Application Publication
(10) Pub. No.: US 2024/0405000 A1
(43) Pub. Date: Dec. 5, 2024

(54) METHOD OF FABRICATING LED LIGHT PLATE, LED LIGHT PLATE, AND DISPLAY DEVICE

(71) Applicant: HKC CORPORATION LIMITED, Shenzhen (CN)

(72) Inventors: Hailong HE, Shenzhen (CN); Lidan YE, Shenzhen (CN)

(21) Appl. No.: 18/641,510

(22) Filed: Apr. 22, 2024

(30) Foreign Application Priority Data
Jun. 2, 2023 (CN) 202310648982.4

(51) Int. Cl. H01L 25/075; H01L 33/38

(52) U.S. Cl. CPC H01L 25/0753; H01L 33/38; H01L 2933/0016

(57) ABSTRACT

A method of fabricating an LED light plate, an LED light plate, and a display device are disclosed. The method includes: disposing a functional layer on each LED chip to form multiple chips to be transferred; placing the chips into a receiving tank filled with a suspension; defining a plurality of grooves matching the shape of the functional layer in the transport substrate; placing the transport substrate into the suspension so that a first electrode in each receiving tank faces each second electrode in the respective groove and that each chip is located between the first electrode and the respective second electrode; energizing the first electrode and each second electrode, so that each chip is absorbed by the transporting substrate, and each functional layer is moved into the respective groove; and transplanting the multiple chips onto a target substrate; where each functional layer is filled with multiple charged particles.

### CROSS-REFERENCE TO RELATED APPLICATIONS

This application claims the priority and benefit of Chinese patent application number 202310648982.4, titled “Method of Fabricating Led Light Plate, Led Light Plate, and Display Device” and filed Jun. 2, 2023 with China National Intellectual Property Administration, the entire contents of which are incorporated herein by reference.

### TECHNICAL FIELD

This application relates to the field of display technology, and more particularly relates to a method of fabricating an LED light plate and an LED light plate.

### BACKGROUND

The description provided in this section is intended for the mere purpose of providing background information related to the present application but doesn't necessarily constitute prior art.

With the development of display technology, Mini-LED display devices and Micro-LED display devices have begun to be used. Each pixel in a Mini-LED display device and a Micro-LED display device corresponds to an LED chip, and so can be addressed and driven to light up independently. In the actual production process, the LED chips need to be welded on the target substrate to form a light plate. This process is known in the industry as mass transfer.

Tens of thousands of LED chips may need to be welded on the target substrate in an LED display device. Therefore, how to efficiently and accurately transfer the LED chips to the target substrate while avoiding damage to the LED chips during the transfer process has become an urgent problem to be solved.

### SUMMARY

In view of the above, it is therefore a purpose of this application to provide a method of fabricating an LED light plate, an LED light plate, and a display device to improve production efficiency and avoid affecting the functionality of the LED chip.

This application discloses a method of fabricating an LED light plate, which includes:
disposing functional layers on the surfaces of multiple LED chips to form chips to be transferred;
placing the chips to be transferred into a receiving tank filled with a suspension;
defining a plurality of grooves matching the shape of the functional layer in the transport substrate;
placing the transport substrate into the suspension, so that a first electrode in the receiving tank is disposed opposite to a second electrode in the groove, and the chip to be transferred is located between the first electrode and the second electrode;
energizing the first electrode and the second electrode, absorbing the chip to be transferred by the transport substrate, and causing the functional layer to move into the groove; and
transplanting the chip to be transferred on the transport substrate onto the target substrate;
where the functional layer is filled with charged particles.

Optionally, the step of arranging functional layers on the surfaces of multiple LED chips to form chips to be transferred specifically includes:
mixing charged particles in the photoresist to form a photoresist with charged particles;
coating the photoresist with charged particles on the surfaces of multiple LED chips; and
exposing and developing the photoresist with charged particles to set functional layers on the surfaces of multiple LED chips to form the chips to be transferred.

Optionally, in the step of exposing and developing the photoresist with charged particles to set functional layers on the surfaces of multiple LED chips to form chips to be transferred,
the photoresist is exposed and developed using a mask, and a plurality of nested annular portions are disposed on the mask corresponding to the functional layer, and taking an outward extending direction along the annular portions as a first direction, along the first direction, the light transmittance of the plurality of nested annular portions gradually becomes smaller.

Optionally, before the step of coating the photoresist with charged particles on the surfaces of the multiple LED chips, the method further includes:
disposing a protective layer on the surface of each of the LED chips.

Optionally, after the step of energizing the first electrode and the second electrode, absorbing the chip to be transferred by the transport substrate, and moving the functional layer into the groove, the method further includes:
confirming a position of each groove where the LED chip is not attached, and marking the second electrode in the groove position where the LED chip is not attached.

Optionally, after the step of transplanting the chip to be transferred on the transport substrate onto the target substrate, the method further includes:
placing the transport substrate into the suspension so that the first electrode and the second electrode face each other, and the chip to be transferred is located between the first electrode and the second electrode;
energizing the first electrode and supplying power to only the marked second electrode;
transplanting the chip to be transferred on the transport substrate to a position on the target substrate where no chip to be transferred is arranged.

Optionally, the chips to be transferred include a first chip and a second chip.

The charged particles in the functional layer on the first chip include positively charged particles of titanium dioxide.

The charged particles of the functional layer on the second chip include negatively charged carbon black particles. The charged particles in the functional layer on the second chip include positively charged particles of titanium dioxide.

Optionally, the chips to be transferred include at least a third chip and a fourth chip.

The content of charged particles in the functional layer on the third chip is greater than the content of charged particles in the functional layer on the fourth chip.

Optionally, a side of the LED chip facing away from the functional layer is provided with a soldering electrode, which is a ring electrode.

Optionally, the step of transplanting the chip to be transferred on the transport substrate onto the target substrate includes:
aligning and bonding the side of the transport substrate on which the chip to be transferred is attached with the target substrate;
arranging an auxiliary substrate on a side of the target substrate facing away from the transport substrate;
energizing the third electrode on the auxiliary substrate to form an absorption force on the chip to be transferred on the target substrate;
reversing the polarity of the second electrode; and
finally removing the transport substrate.

This application further discloses an LED light plate, which is fabricated by the above-mentioned method of fabricating the LED light plate.

This application further discloses a display device. The display device includes a display panel and a backlight module. The display panel and the backlight module are arranged oppositely. The backlight module includes an LED light plate. The LED light plate provides a backlight for the display panel.

Compared with the solution of transplanting LED chips to the target substrate one by one, this application directly absorbs a large number of LED chips by the transporting substrate and then transfers them to the target substrate, which improves production efficiency. Furthermore, a functional layer is also set on the surface of the LED chip, and charged particles are also disposed in the functional layer. Compared with the method of directly setting charges on the surface of the LED chip, the charged particles are prevented from directly contacting the LED chip, which may otherwise result in the inability to remove the charged particles and the occurrence of the problem that the charged particles remaining on the surface of the LED chip affects the light emission of the LED chip.

### BRIEF DESCRIPTION OF DRAWINGS

The accompanying drawings are used to provide a further understanding of the embodiments according to this application, and constitute a part of the specification. They are used to illustrate the embodiments according to this application, and explain the principle of this application in conjunction with the text description. Apparently, the drawings in the following description merely represent some embodiments of the present disclosure, and for those having ordinary skill in the art, other drawings may also be obtained based on these drawings without investing creative efforts. A brief description of the accompanying drawings is provided as follows.

FIG. 1 is a schematic diagram of a display device according to an embodiment of this application.

FIG. 2 is a schematic diagram of an LED light plate according to an embodiment of this application.

FIG. 3 is a schematic flow chart of a method of fabricating an LED light plate according to a first embodiment of this application.

FIG. 4 is a schematic process diagram of a method of fabricating an LED light plate according to the first embodiment of this application.

FIG. 5 is a partially enlarged schematic diagram of an LED light plate according to the first embodiment of this application.

FIG. 6 is a schematic flowchart of a method of disposing functional layers according to the first embodiment of this application.

FIG. 7 is a schematic diagram of a chip to be transferred according to the first embodiment of this application.

FIG. 8 is a schematic diagram of a mask according to the first embodiment of this application.

FIG. 9 is a schematic diagram illustrating a chip to be transferred according to the first embodiment of this application.

FIG. 10 is a schematic diagram illustrating a groove according to the first embodiment of this application.

FIG. 11 is a schematic flow chart of ensuring that each pad on the target substrate is transplanted with an LED chip according to the first embodiment of this application.

FIG. 12 is a schematic diagram illustrating how to transplant a chip to be transferred according to the first embodiment of this application.

FIG. 13 is a schematic diagram of two different LED chips contained in the same receiving tank according to a second embodiment of this application.

FIG. 14 is a schematic diagram of two different LED chips contained in the same receiving tank according to the second embodiment of this application.

In the drawings: 10. Chip to be transferred; 110. LED chip; 120. Protective layer; 130. Functional layer; 131. Limiting protrusion; 132. Ring electrode; 133. Cavity; 141. First chip; 142. Second Chip; 143. Third chip; 144. Fourth chip; 200. Receiving tank; 210. First electrode; 220. Suspension; 300. Transporting substrate; 310. Groove; 311. Limiting slot; 320. Second electrode; 400. Target substrate; 500. Mask; 510. Annular portion; 700. Display device; 710. Display panel; 720. Backlight module; 721. LED light plate.

### DETAILED DESCRIPTION OF EMBODIMENTS

It should be understood that the terms used herein, the specific structures and function details disclosed herein are intended for the mere purposes of describing specific embodiments and are representative. However, this application may be implemented in many alternative forms and should not be construed as being limited to the embodiments set forth herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. Term “comprising”, “including”, and any variants thereof mean non-exclusive inclusion, so that one or more other features, integers, steps, operations, units, components, and/or combinations thereof may be present or added.

In addition, terms “center”, “transverse”, “up”, “down”, “left”, “right”, “vertical”, “horizontal”, “top”, “bottom”, “inside”, “outside”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure.

Furthermore, as used herein, terms “installed on”, “mounted on”, “connected to”, “coupled to”, “connected with”, and “coupled with” should be understood in a broad sense unless otherwise specified and defined. For example, they may indicate a fixed connection, a detachable connection, or an integral connection. They may denote a mechanical connection, or an electrical connection. They may denote a direct connection, a connection through an intermediate, or an internal connection between two elements. For those of ordinary skill in the art, the specific meanings of the above terms as used in this application can be understood depending on specific contexts.

Hereinafter this application will be described in further detail with reference to the accompanying drawings and some optional embodiments.

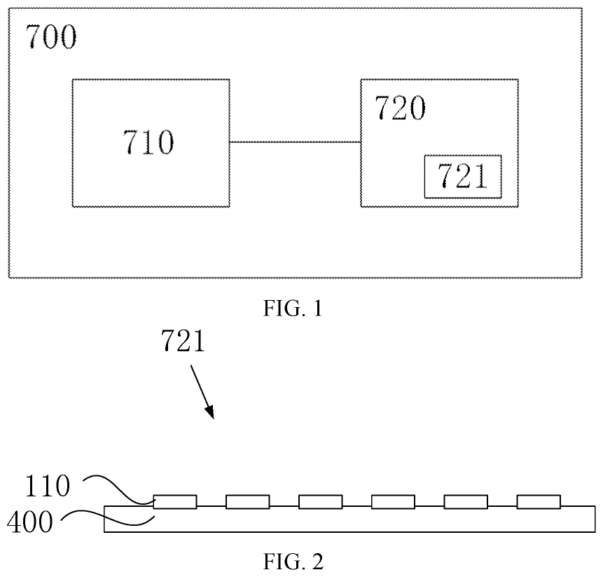

FIG. 1 is a schematic diagram of a display device according to an embodiment of this application. As shown in FIG. 1, this application discloses a display device 700. The display device 700 includes a display panel 710 and a backlight module 720. The display panel 710 and the backlight module 720 are arranged opposite to each other. The backlight module 720 includes an LED light plate 721. The LED light plate 721 provides backlight for the display panel 710.

The display panel 710 includes, for example, a TN (Twisted Nematic) display panel 710, an IPS (In-Plane Switching) display panel 710, a VA (Vertical Alignment) display panel 710, and an MVA (Multi-Domain Vertical Alignment) display panel 710.

FIG. 2 is a schematic diagram of an LED light plate according to an embodiment of this application. As shown in FIG. 2, this application discloses an LED light plate 721. The LED light plate 721 includes a target substrate 400 and an LED chip 110. The LED chip 110 is disposed on the target substrate 400. The LED light plate 721 is used to provide backlight for the display panel.

Regarding the method of fabricating LED light plate 721, this application provides the following design.

### Embodiment 1

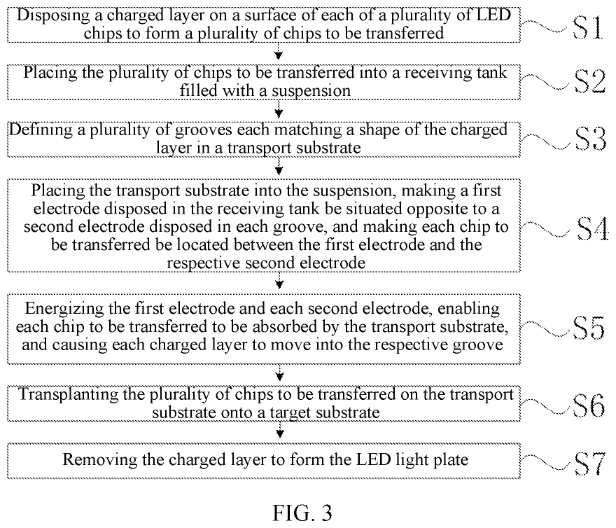

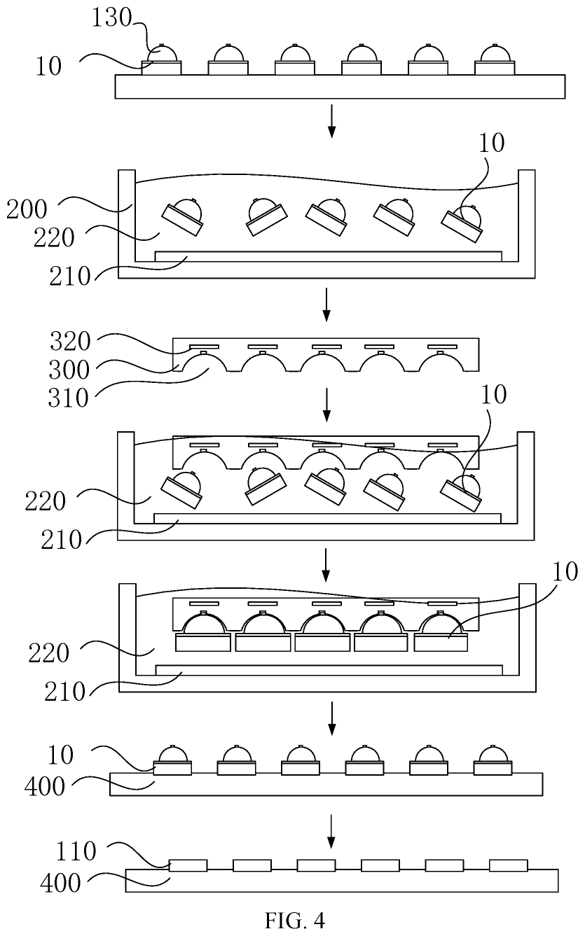

FIG. 3 is a schematic flow chart of a method of fabricating an LED light plate according to the first embodiment of this application. As shown in FIGS. 3-4, this application discloses a method of fabricating an LED light plate. The method includes:
S1: disposing a functional layer on a surface of each of multiple LED chips to form chips to be transferred;
S2: placing the chip to be transferred into a receiving tank filled with a suspension;
S3: defining multiple grooves matching the shape of the functional layer in the transport substrate;
S4: placing the transport substrate into the suspension, so that a first electrode in the receiving tank is opposite to a second electrode in the groove, and the chip to be transferred is located between the first electrode and the second electrode;
S5: energizing the first electrode and the second electrode, so that the chip to be transferred is absorbed by the transport substrate and the functional layer is moved into the groove; and
S6: transplanting the chip to be transferred on the transport substrate onto the target substrate;
S7: removing the functional layer to form the LED light plate;

The functional layer 130 may be filled with charged particles. The LED chips 110 described in this application include Mini-LED chips 110 and Micro-LED chips 110. This method can be applied to both Mini-LED chip 110 and Micro-LED chip 110. The target substrate 400 is provided with welding pads corresponding to a plurality of LED chips 110, and the LED chips 110 are fixed to the target substrate 400 by welding.

The suspension 220 is a mixture of isoparaffin and silicone oil. This allows the chips 10 to be transferred to be suspended in the receiving tank 200 without all being deposited at the bottom of the receiving tank 200, thereby improving the reliability of transplantation.

The plurality of LED chips 110 are arranged in a matrix. The functional layer 130 is provided on the surface of each LED chip 110, and then the chip 10 to be transferred is put into the receiving tank 200, and the chip 10 to be transferred in the receiving tank 200 is transported to the target substrate 400 through the transport substrate 300.

Compared with the solution of transplanting LED chips 110 to the target substrate 400 one by one, this application directly absorbs a large number of LED chips 110 by the transporting substrate 300 and then transfers them to the target substrate 400, which improves production efficiency. Furthermore, charged particles are also disposed in the functional layer 130. Compared with the method of directly setting charges on the surface of the LED chip 110, the charged particles are prevented from directly contacting the LED chip 110, which may otherwise result in the inability to remove the charged particles, so that the residual charged particles on the surface of the LED chip 110 are prevented from affecting the light emission of the LED chip 110.

Of course, it is also possible that the functional layer 130 is made of a light-transmitting material, and in this case step S7 of removing the functional layer 130 to form the LED light plate 721 is not required. In other words, the functional layer 130 is not removed, so that the light emitted by the LED may be diffused by doping diffusion particles in the functional layer 130.

Furthermore, the functional layer 130 may also be set in a lens shape, including a convex lens and a concave lens, so that the functional layer 130 may diffuse/or shrink the light emitted by the LED chip 110, thereby adjusting the light-emitting angle of the LED chip 110.

Alternatively, other implementations include filling the functional layer 130 with phosphor, emitting blue light through the LED chip 110, where the blue light is combined with the phosphor to achieve the effect of emitting white light.

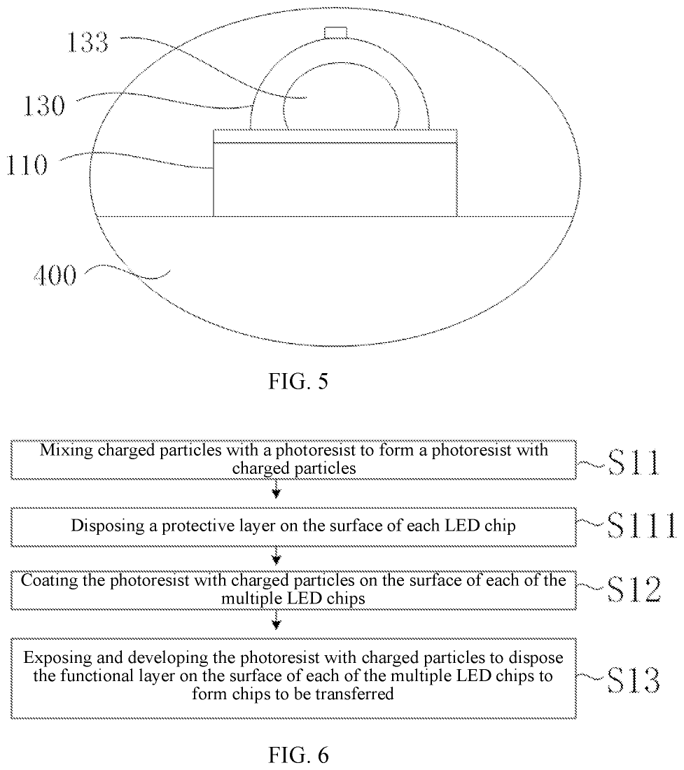

Alternatively, as shown in FIG. 5, a cavity 133 is provided inside the functional layer 130, which is filled with quantum dots or a color filter material, so that the quantum dots are excited by the LED chip 110 to emit light of different colors such as red, green, and blue, or color filters may be used to filter the light emitted by the LED chip 110 to obtain the light of different colors such as red, green, and blue, so that it may be used for a display panel without a color film substrate.

FIG. 6 is a schematic flowchart of a method of disposing a functional layer according to the first embodiment of this application. As shown in FIG. 6, the step S1 of disposing a functional layer on the surface of each of multiple LED chips to form chips to be transferred specifically includes:
S11: mixing charged particles in a photoresist to form a photoresist with charged particles;
S12: coating the photoresist with charged particles on the surface of each of the multiple LED chips;
S13: exposing and developing the photoresist with charged particles to set functional layers on the surfaces of multiple LED chips to form chips to be transferred.

The photoresist with the charged particles is formed by mixing the photoresist and the charged particles in a ratio of 50% to 80%, and then the photoresist with the charged particles is coated on the surface of the LED chip 110. Exposure and development means placing a metal mask 500 on the photoresist, curing the photoresist through light illumination, and finally removing the uncured portion of the photoresist to set the functional layer 130 on the surface of multiple LED chips 110 to form the chips 10 to be transferred.

That is, the LED chip 110 is charged by using a photoresist mixed with charged particles. In the subsequent step S7 of removing the functional layer to form the LED light plate, the functional layer 130 on the chip to be transferred 10 is peeled off and removed using a stripping solution. This will not damage the LED chip 110, will not affect the normal light emission of the LED chip 110, and can also prevent charged particles from remaining on the target substrate 400 or the LED chip 110.

Furthermore, prior to step S12 of coating the photoresist with charged particles on the surface of each of the plurality of LED chips, the following steps are further included:
S111: disposing a protective layer on the surface of the LED chip;

By first arranging the protective layer 120 on the surface of the LED chip 110 and then arranging the functional layer 130 on the protective layer 120, the charged particles in the functional layer 130 may be prevented from remaining on the surface of the LED chip 110 thus causing black spots to appear when the LED chip 110 is displaying. Furthermore, it may also prevent the problem of poor heat dissipation of the LED chip 110 caused by the residual charged particles. In addition, the protective layer 120 may also be removed using laser cutting. This eliminates the need to put the entire target substrate 400 into the stripping solution for stripping, and also prevents other impurities from adhering to the target substrate 400.

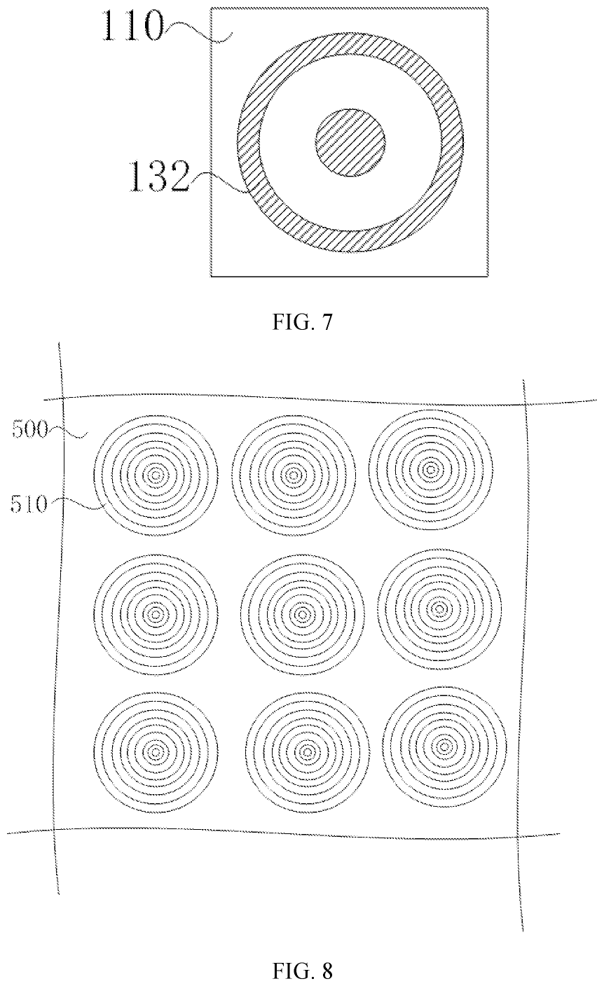

FIG. 7 is a schematic diagram of a chip to be transferred according to the first embodiment of this application. As shown in FIG. 7, a soldering electrode is provided on the side of the LED chip 110 facing away from the functional layer 130, where the soldering electrode is a ring electrode 132.

In this way, even when the chip 10 to be transferred is rotated at a large angle, the chip 10 to be transferred can still be welded to the target substrate 400. Furthermore, when the transport substrate 300 is used to absorb the chip 10 to be transferred, there is no need to consider the issue of docking the soldering electrode with the welding pad on the target substrate 400, thereby improving work efficiency.

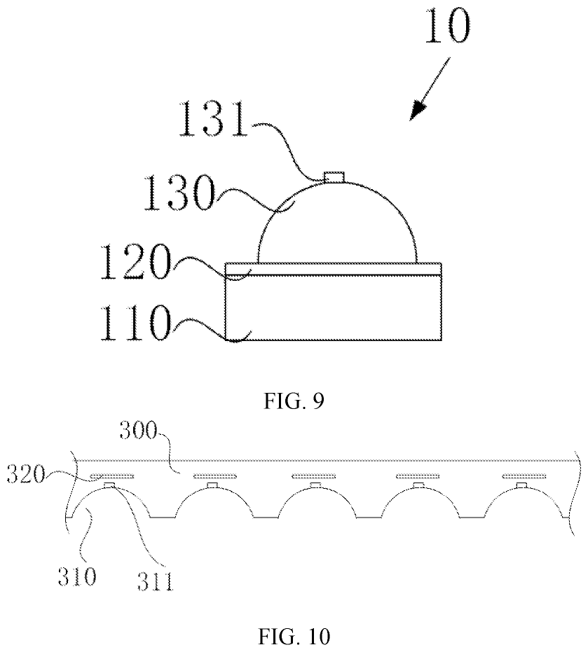

FIG. 8 is a schematic diagram of a mask according to the first embodiment of this application. FIG. 9 is a schematic structural diagram of a chip to be transferred according to the first embodiment of this application. FIG. 10 is a schematic structural diagram of a groove according to the first embodiment of this application. Referring to FIGS. 8-10 in conjunction,

FIG. 8 exemplarily shows patterns corresponding to multiple LED chips 110 on a mask 500, where each pattern corresponds to one LED chip 110. In step S13 of exposing and developing the photoresist with charged particles to set functional layers on the surfaces of multiple LED chips to form the chips to be transferred,
the photoresist is exposed and developed using a mask 500, so that a plurality of nested annular portions 510 are provided on the mask 500 corresponding to each functional layer 130 thus forming a pattern. Taking the outward extending direction along the annular portions 510 as a first direction, along the first direction, the light transmittance of the plurality of nested annular portions 510 gradually becomes less. As such, the shape of the functional layer 130 is hemispherical, and the shape of the groove 310 matches the shape of the functional layer 130.

Further, a limiting slot 311 is provided at the bottom of the groove 310, and a limiting protrusion 131 is provided on the functional layer 130. After the transfer substrate 300 absorbs the chip 10 to be transferred, the limiting protrusion 131 is inserted into the limiting slot 311, thereby avoiding the problem of the chip 10 to be transferred being offset from the groove 310.

In step S5 of energizing the first electrode and the second electrode, absorbing the chip to be transferred by the transport substrate, and moving the functional layer into the groove, the following operation is further included:
S51: shaking the transport substrate after the transport substrate leaves a liquid level of the suspension in the receiving tank.

Furthermore, the diameter of the functional layer 130 may be smaller than the length of the LED chip 110. In this way, after the transport substrate 300 absorbs the chip 10 to be transferred, only the functional layer 130 enters the groove 310. When the chip to be transferred 10 is flipped over and absorbed onto the transport substrate 300, the LED chip 110 will be partially stuck outside the groove 310, so that the chip to be transferred 10 stuck outside the groove 310 can be shaken out.

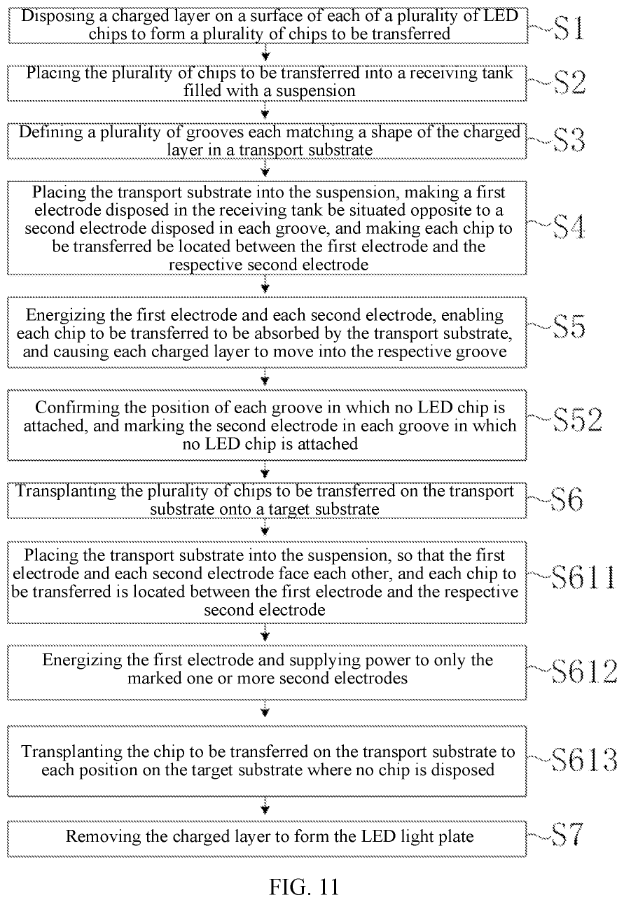

FIG. 11 is a schematic flow chart of ensuring that each pad on the target substrate is transplanted with an LED chip according to the first embodiment of this application. As shown in FIG. 11, subsequent to step S5 of energizing the first electrode and the second electrode, absorbing the chip to be transferred by the transport substrate, and moving the functional layer into the groove, the method further includes:
S52: confirming the position of the groove where the LED chip is not attached, and marking the second electrode in the groove position where the LED chip is not attached.

The grooves 310 in the transport substrate 300 are arranged in a matrix, and the transport substrate 300 is provided with a current detector and a plurality of crisscrossing scanning lines and data lines. A second electrode 320 is disposed in each groove 310, and each second electrode 320 is connected to an adjacent scan line and an adjacent data line through an active switch.

After the groove 310 in the target substrate 400 absorbs the chip 10 to be transferred, a reflow circuit is formed, while the second electrode 320 in the groove 310 that does not absorb a chip 10 to be transferred is an open circuit. By detecting a signal change on the second electrode 320 by the current detector, the position of the groove 310 where the LED chip 110 is not attached can be determined.

Therefore, it can be directly determined which groove 310 in the transport substrate 300 does not have the chip 10 to be transferred attached thereto. Furthermore, there is no need to add unnecessary operations of photographing the target substrate 400, scanning the photographed image, and inputting into the transport substrate 300 the position of the groove 310 of the transport substrate 300 that is not attached with the chip 10 to be transferred, thereby improving work efficiency.

Furthermore, after the step S6 of transplanting the chip to be transferred on the transport substrate onto the target substrate, the method further includes:
S611: placing the transport substrate into the suspension, so that the first electrode and the second electrode face each other, and the chip to be transferred is positioned between the first electrode and the second electrode;
S612: energizing the first electrode and supplying power to only the second electrode of the mark;
S613: transplanting the chip to be transferred on the transport substrate to a position on the target substrate where the chip to be transferred is not disposed.

That is, in the process of transplanting the chips 10 to be transferred to the target substrate 400 for the first time, it can be detected which grooves 310 in the transport substrate 300 are not attached with the chip 10 to be transferred.

After the chips 10 to be transferred are transplanted to the target substrate 400 for the first time, a second supplementary transfer is performed. The second supplementary transfer only energizes the second electrode 320 in the groove 310 in the transport substrate 300 where the chip 10 to be transferred is not attached in the first time, thereby preventing the lack of the LED chips 110 on the target substrate 400 and preventing the normal light emission of the target substrate 400 from being affected.

The above steps S52-S613 are repeatedly performed until all the soldering pads on the target substrate 400 are soldered with the chip 10 to be transferred, and finally a photoresist stripping solution is used to remove the functional layer 130 on the chips 10 to be transferred.

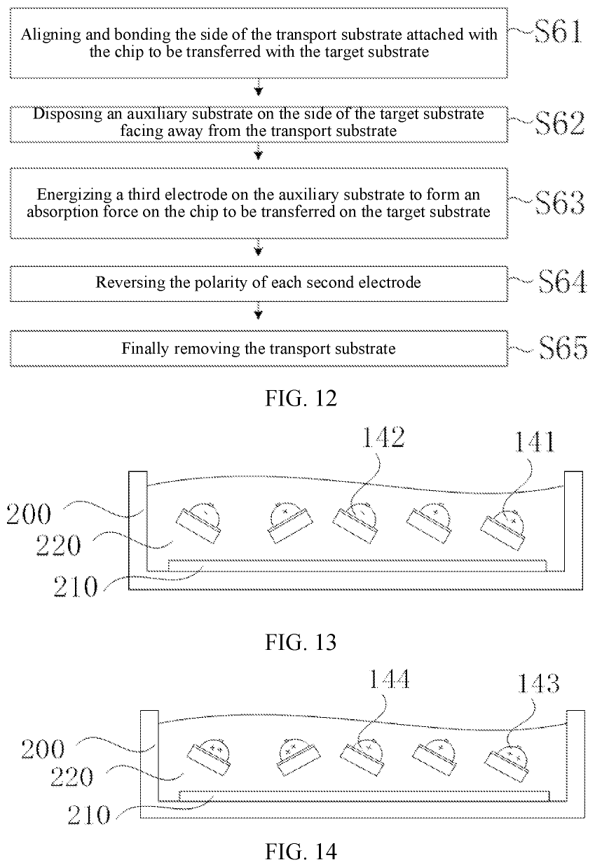

As shown in FIG. 3 and FIG. 12, the step S6 of transplanting the chip to be transferred on the transport substrate onto the target substrate specifically includes:
S61: aligning and bonding the side of the transport substrate attached with the chip to be transferred with the target substrate;
S62: disposing an auxiliary substrate on the side of the target substrate facing away from the transport substrate;
S63: turning on a third electrode on the auxiliary substrate to form an absorption force on the chip to be transferred on the target substrate;
S64: reversing the polarity of the second electrode; and
S65: finally removing the transport substrate.

This ensures that all the chips 10 to be transferred on the transport substrate 300 are transplanted to the target substrate 400, and prevents the annular electrode 132 on the chip 10 to be transferred from being displaced from the welding pad on the target substrate 400 after the transport substrate 300 is removed from the target substrate 400.

### Embodiment 2

As shown in FIG. 13, the second embodiment of this application is different from the first embodiment in that when two different LED chips 110 need to be transferred, functional layers 130 of different polarities can be provided for the two different LED chips 110.

Specifically, the chip to be transferred 10 includes a first chip 141 and a second chip 142. The charged particles in the functional layer 130 on the first chip 141 include positively charged particles of titanium dioxide. The charged particles of the functional layer 130 on the second chip 142 include negatively charged carbon black particles.

When it is required to absorb the first chip 141, the first electrode 210 is energized with positive charges and the second electrode 320 is energized with negative charges, so that the first chip 141 can be absorbed by the groove 310 in the transport substrate 300. When it is required to absorb the second chip 142, the first electrode 210 is energized with negative charges and the second electrode 320 is energized with positive charges, so that the second chip 142 can be absorbed by the groove 310 in the transport substrate 300. Compared with the first embodiment, this embodiment can transfer two different types of chips 10 to be transferred in the same receiving tank 200, thereby improving production efficiency.

### Embodiment 3

As shown in FIG. 14, the third embodiment of this application is different from the first embodiment in that when two different LED chips 110 need to be transferred, they can be distinguished by making the charge amounts of the two different chips 10 to be transferred different.

Specifically, the chip to be transferred 10 at least includes a third chip 143 and a fourth chip 144. The content of charged particles in the functional layer 130 on the third chip 143 is greater than the content of charged particles in the functional layer 130 on the fourth chip 144.

Furthermore, the content of charged particles in the functional layer 130 on the fourth chip 144 is 25%-50% of the content of charged particles in the functional layer 130 to ensure that there is a difference of more than 50% in the electric field forces received by the functional layer 130 of the fourth chip 144 and received by the functional layer 130 of the third chip 143 under the same voltage, so as to avoid accidentally absorbing the fourth chip 144 when absorbing the third chip 143.

Compared with the second embodiment in which two different LED chips 110 are provided with functional layers 130 of different polarities, this embodiment can transfer multiple different types of chips 10 to be transferred in the same receiving tank 200.

It should be noted that the limitations of various operations involved in this solution will not be deemed to limit the order of the operations, provided that they do not affect the implementation of the specific solution, so that the operations written earlier may be executed earlier or they may also be executed later or even at the same time. As long as the solution can be implemented, they should all be regarded as falling in the scope of protection of this application.

It should be noted that the inventive concept of this application can be formed into many embodiments, but the length of the application document is limited and so these embodiments cannot be enumerated one by one. The technical features can be arbitrarily combined to form a new embodiment, and the original technical effect may be enhanced after the various embodiments or technical features are combined.

The foregoing is merely a further detailed description of this application with reference to some specific illustrative embodiments, but the specific implementations of this application are not to be construed to be limited to these illustrative embodiments. For those having ordinary skill in the technical field to which this application pertains, numerous deductions or substitutions may be made without departing from the concept of this application, which shall all be regarded as falling in the scope of protection of this application.

What is claimed is:

1. A method of fabricating an LED light plate, comprising:
disposing a functional layer on a surface of each of a plurality of LED chips to form a plurality of chips to be transferred;
placing the plurality of chips to be transferred into a receiving tank filled with a suspension;
defining a plurality of grooves each matching a shape of the functional layer in a transport substrate;
placing the transport substrate into the suspension, making a first electrode disposed in the receiving tank be situated opposite to a second electrode disposed in each groove, and making each chip to be transferred be located between the first electrode and the respective second electrode;
energizing the first electrode and each second electrode, enabling each chip to be transferred to be absorbed by the transport substrate, and causing each functional layer to move into the respective groove; and
transplanting the plurality of chips to be transferred on the transport substrate onto a target substrate;
wherein each functional layer is filled with a plurality of charged particles.

2. The method as recited in claim 1, wherein the operation of disposing a functional layer on a surface of each of a plurality of LED chips to form a plurality of chips to be transferred comprises:
mixing a plurality of charged particles with a photoresist to form a photoresist with a plurality of charged particles;
coating the photoresist mixed with the plurality of charged particles on the surface of each of the plurality of LED chips; and
exposing and developing the photoresist mixed with the plurality of charged particles to dispose the functional layer on the surface of each of the plurality of LED chips to form the plurality of chips to be transferred.

3. The method as recited in claim 2, wherein the operations of exposing and developing the photoresist mixed with the plurality of charged particles to dispose the functional layer on the surface of each of the plurality of LED chips to form the plurality of chips to be transferred comprise:
exposing and developing the photoresist using a mask, wherein there is disposed a plurality of nested annular portions on the mask corresponding to each functional layer; wherein let a direction extending outward along the plurality of annular portions be a first direction, a light transmittance of each of the plurality of nested annular portions gradually becomes less along the first direction.

4. The method as recited in claim 2, further comprising the following operation prior to the operation of coating the photoresist mixed with the plurality of charged particles on the surface of each of the plurality of LED chips:
disposing a protective layer on the surface of each of the plurality of LED chips.

5. The method as recited in claim 1, further comprising the following operations subsequent to the operations of energizing the first electrode and the second electrode, enabling each chip to be transferred to be absorbed by the transport substrate, and causing each functional layer to move into the respective groove:
determining a position of each groove in which no LED chip is attached, and
marking the second electrode in each groove in which no LED chip is attached.

6. The method as recited in claim 5, further comprising the following operations subsequent to the operation of transplanting the plurality of chips to be transferred on the transport substrate onto the target substrate:
placing the transport substrate into the suspension, making the first electrode and each second electrode face each other, and making each chip to be transferred be located between the first electrode and the respective second electrode:
energizing the first electrode and supplying power to only the marked one or more second electrodes; and
transplanting the chip to be transferred on the transport substrate to each position on the target substrate where no chip to be transferred is disposed.

7. The method as recited in claim 6, wherein the plurality of grooves in the transport substrate are disposed in a matrix, and wherein the transport substrate comprises a current detector and a plurality of crisscrossing scan lines and data lines,
wherein there is disposed a second electrode in each groove, and wherein each second electrode is connected to an adjacent scan line and an adjacent data line through a respective active switch;
wherein after each chip to be transferred is absorbed into the respective groove in the target substrate, a reflow circuit is formed, while the second electrode in each groove in which no chip is absorbed is an open circuit; wherein the current detector is configured to detect a signal change on each second electrode to determine the position of each groove in which no LED chip is attached.

8. The method as recited in claim 1, wherein there is disposed a soldering electrode on a side of each LED chip facing away from the respective functional layer, the soldering electrode being a ring electrode.

9. The method as recited in claim 1, wherein a limiting slot is defined in a bottom of each groove, and wherein a limiting protrusion is disposed on each functional layer; wherein after the transport substrate absorbs each chip to be transferred, the respective limiting protrusion of the corresponding functional layer is inserted into the respective limiting slot in the corresponding groove.

10. The method as recited in claim 1, wherein the operations of energizing the first electrode and each second electrode, enabling each chip to be transferred to be absorbed by the transport substrate, and causing each functional layer to move into the respective groove comprise:
shaking the transport substrate after the transport substrate leaves a liquid level of the suspension disposed in the receiving tank.

11. The method as recited in claim 1, wherein the operation of transplanting the plurality of chips to be transferred on the transport substrate onto the target substrate comprises:
aligning and bonding a side of the transport substrate on which the plurality of chips to be transferred are attached with the target substrate;
disposing an auxiliary substrate on a side of the target substrate facing away from the transport substrate;
energizing a third electrode disposed on the auxiliary substrate to generate an absorption force on the plurality of chips to be transferred on the target substrate;
reversing a polarity of each second electrode; and
removing the transport substrate.

12. The method as recited in claim 1, wherein there is defined a cavity inside each functional layer, and wherein the cavity is filled with quantum dots or a color filter material.

13. The method as recited in claim 1, further comprising the following operations subsequent to the operation of transplanting the plurality of chips to be transferred on the transport substrate onto the target substrate:
removing the functional layer of each of the plurality of LED chips to obtain the LED light plate.

14. The method as recited in claim 1, wherein there is doped a plurality of diffusion particles in each functional layer.

15. The method as recited in claim 1, wherein each functional layer has the shape of a lens.

16. The method as recited in claim 1, wherein the plurality of chips to be transferred comprise a first chip and a second chip;
wherein the plurality of charged particles in the functional layer on the first chip comprise positively charged Titanium dioxide particles; and
wherein the plurality of charged particles of the functional layer on the second chip comprise negatively charged carbon black particles.

17. The method as recited in claim 1, wherein the plurality of chips to be transferred comprise at least a third chip and a fourth chip;
wherein a content of charged particles in the functional layer on the third chip is greater than a content of charged particles in the functional layer on the fourth chip.

18. The method as recited in claim 17, wherein a content of charged particles in the functional layer on the fourth chip is 25%-50% of a content of charged particles in the functional layer of the third chip.

19. An LED light plate, fabricated by a method comprising:
disposing a functional layer on a surface of each of a plurality of LED chips to form a plurality of chips to be transferred;
placing the plurality of chips to be transferred into a receiving tank filled with a suspension;
defining a plurality of grooves each matching a shape of the functional layer in a transport substrate;
placing the transport substrate into the suspension, making a first electrode disposed in the receiving tank be situated opposite to a second electrode disposed in each groove, and making each chip to be transferred be located between the first electrode and the respective second electrode;
energizing the first electrode and each second electrode, enabling each chip to be transferred to be absorbed by the transport substrate, and causing each functional layer to move into the respective groove; and
transplanting the plurality of chips to be transferred on the transport substrate onto a target substrate;
wherein each functional layer is filled with a plurality of charged particles.

20. A display device, comprising a display panel and a backlight module, the display panel being disposed opposite to the backlight module, wherein the backlight module comprises the LED light plate configured to provide backlight for the display panel, wherein the LED light plate is fabricated by a method comprising:
disposing a functional layer on a surface of each of a plurality of LED chips to form a plurality of chips to be transferred;
placing the plurality of chips to be transferred into a receiving tank filled with a suspension;
defining a plurality of grooves each matching a shape of the functional layer in a transport substrate;
placing the transport substrate into the suspension, making a first electrode disposed in the receiving tank be situated opposite to a second electrode disposed in each groove, and making each chip to be transferred be located between the first electrode and the respective second electrode;
energizing the first electrode and each second electrode, enabling each chip to be transferred to be absorbed by the transport substrate, and causing each functional layer to move into the respective groove; and
transplanting the plurality of chips to be transferred on the transport substrate onto a target substrate;
wherein each functional layer is filled with a plurality of charged particles.
